(19) United States
(12) Patent Application Publication
(10) Pub. No.: US 2025/0203898 A1
(43) Pub. Date: Jun. 19, 2025

(54) SEMICONDUCTOR DEVICE

(71) Applicant: ROHM CO., LTD., Kyoto-shi (JP)

(72) Inventor: Nobutaka OI, Kyoto-shi (JP)

(73) Assignee: ROHM CO., LTD., Kyoto-shi (JP)

(21) Appl. No.: 19/073,077

(22) Filed: Mar. 7, 2025

(30) Foreign Application Priority Data
Sep. 9, 2022 (JP) 2022-143916

(51) Int. Cl. H10D 12/00; H10D 12/01; H10D 62/13; H10D 64/23

(52) U.S. Cl. CPC H10D 12/481; H10D 62/145; H10D 64/232; H10D 12/035; H10D 12/038

(57) ABSTRACT

A semiconductor device including a gate electrode layer embedded in a gate trench, a contact trench including a first intersection region intersecting the gate trench, and an emitter contact electrode layer embedded in the contact trench, in which gate electrode recess portions are formed in the first intersection region in the gate trench and a peripheral portion of the first intersection region, a gate covering insulating layer is embedded in the gate electrode recess portion, and the emitter region is formed deeper than an upper surface of the gate electrode layer in the periphery of the first intersection region.

### CROSS-REFERENCE TO RELATED APPLICATIONS

The present application is a bypass continuation of International Application No. PCT/JP2023/030991 filed Aug. 28, 2023, which corresponds to Japanese Patent Application No. 2022-143916 filed on Sep. 9, 2022 in the Japan Patent Office, and the entire disclosure of these applications are incorporated herein by reference.

### TECHNICAL FIELD

The present disclosure relates to a semiconductor device.

### BACKGROUND ART

Patent Literature 1 (WO 2019/103135) discloses a semiconductor device that includes a semiconductor layer that has a principal surface in which a trench is formed, a body region of a first conductivity type formed along a side wall of the trench in a surface portion of the principal surface of the semiconductor layer, an impurity region formed of a second conductivity type along the side wall of the trench in a surface portion of the body region, a gate insulating layer formed on an inner wall of the trench, a gate electrode that is embedded in the trench and faces the body region and the impurity region across the gate insulating layer, a contact electrode that passes through the side wall of the trench from inside the trench and is led out to the surface portion of the principal surface of the semiconductor layer and is electrically connected to the body region and the impurity region, and an embedded insulating layer that is interposed between the gate electrode and the contact electrode in the trench and insulates the gate electrode and the contact electrode.

### BRIEF DESCRIPTION OF DRAWINGS

FIG. 1 is a schematic cross-sectional perspective view illustrating a partial region of a semiconductor device according to a first preferred embodiment of the present disclosure.

FIG. 2 is a diagram in which the structure on a first principal surface of a chip is removed from FIG. 1.

FIG. 3 is a view in which an emitter contact electrode layer is removed from FIG. 2.

FIG. 4 is a schematic plan view of FIG. 3 as viewed from the first principal surface of the chip.

FIG. 5 is a cross-sectional view taken along line V-V illustrated in FIG. 4.

FIG. 6 is a cross-sectional view taken along line VI-VI illustrated in FIG. 4.

FIG. 7 is a cross-sectional view taken along line VII-VII illustrated in FIG. 4.

FIGS. 8A to 8N are diagrams illustrating an example of a method of manufacturing the semiconductor device.

FIG. 9A is a diagram for explaining channel formation of a semiconductor device according to Condition 1.

FIG. 9B is a diagram for explaining an arrangement pattern of an emitter region and a contact region of the semiconductor device according to Condition 1.

FIG. 10A is a diagram for explaining channel formation of a semiconductor device according to Condition 2.

FIG. 10B is a diagram for explaining an arrangement pattern of an emitter region and a contact region of the semiconductor device according to Condition 2.

FIG. 11 is a graph in which short circuit waveforms of the semiconductor devices according to Conditions 1 and 2 are obtained by simulation.

FIG. 12 is a graph in which current-voltage characteristics of the semiconductor devices according to Conditions 1 and 2 are obtained by simulation.

FIG. 13 is an enlarged view of a part of the graph of FIG. 12.

FIG. 14 is a graph in which current-voltage characteristics of the semiconductor devices according to Conditions 1 and 2 are obtained by simulation.

FIG. 15 is a schematic cross-sectional perspective view illustrating a partial region of a semiconductor device according to a second preferred embodiment of the present disclosure.

FIG. 16 is a schematic cross-sectional view illustrating a part of the semiconductor device in FIG. 15.

FIG. 17 is a schematic cross-sectional view illustrating a part of the semiconductor device in FIG. 15.

FIG. 18 is a schematic cross-sectional perspective view illustrating a partial region of a semiconductor device according to a third preferred embodiment of the present disclosure.

### DESCRIPTION OF EMBODIMENTS

### <<Description of Structure of Semiconductor Device 1 (First Preferred Embodiment)>>

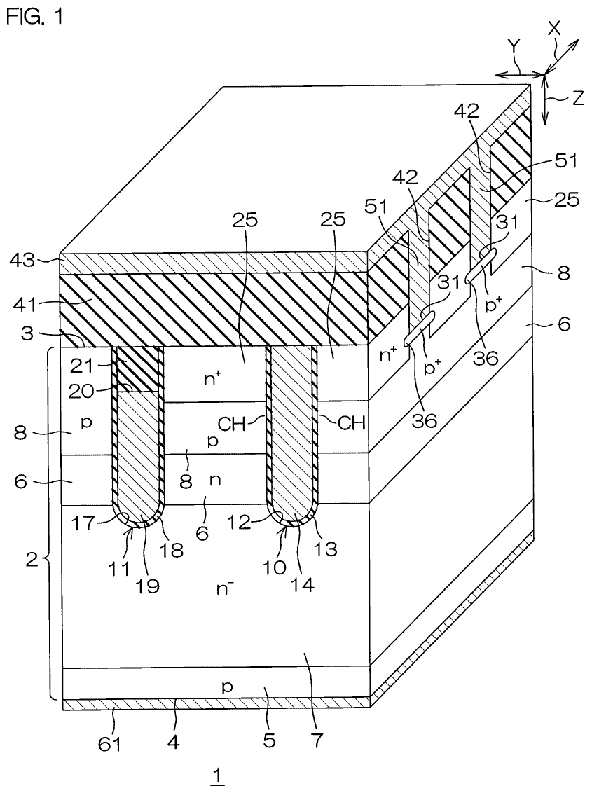

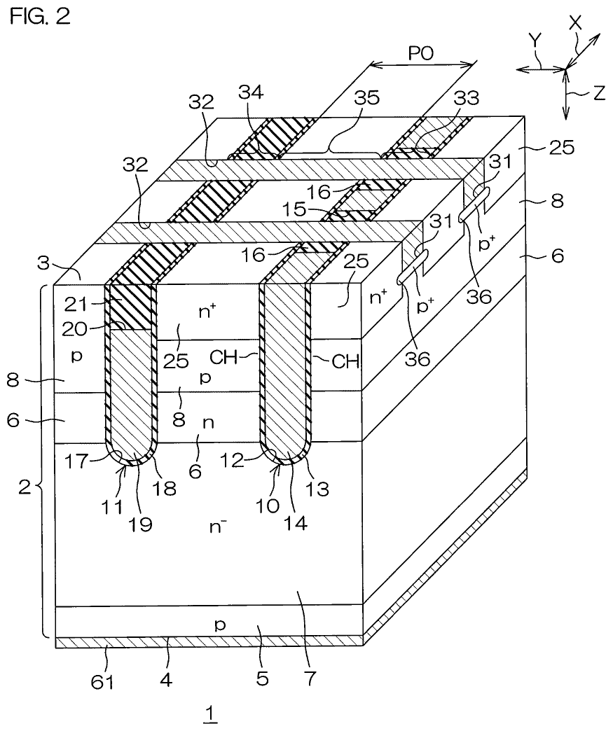

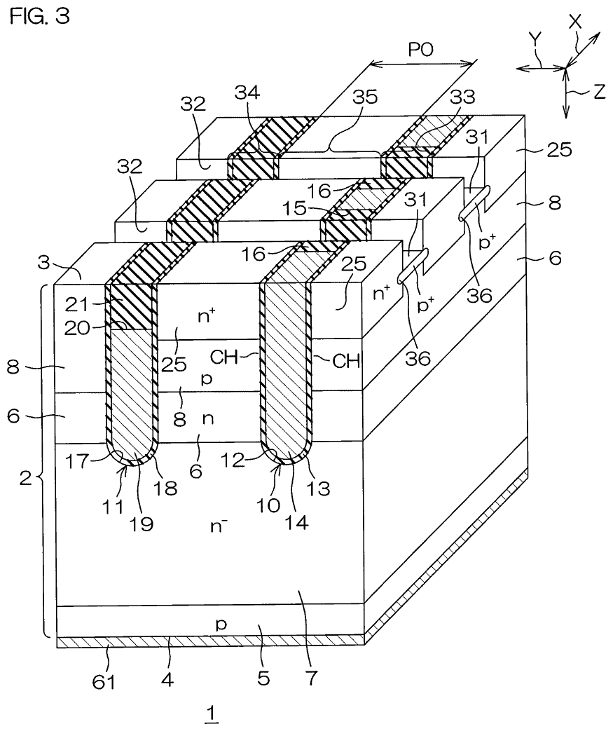

FIG. 1 is a schematic cross-sectional perspective view illustrating a partial region of a semiconductor device 1 according to a first preferred embodiment of the present disclosure. FIG. 2 is a diagram in which the structure on a first principal surface 3 of a chip 2 is removed from FIG. 1. FIG. 3 is a view in which an emitter contact electrode layer 51 is removed from FIG. 2.

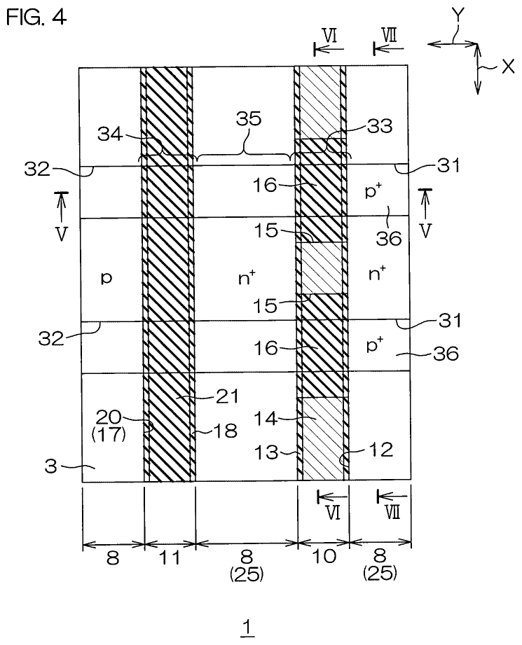

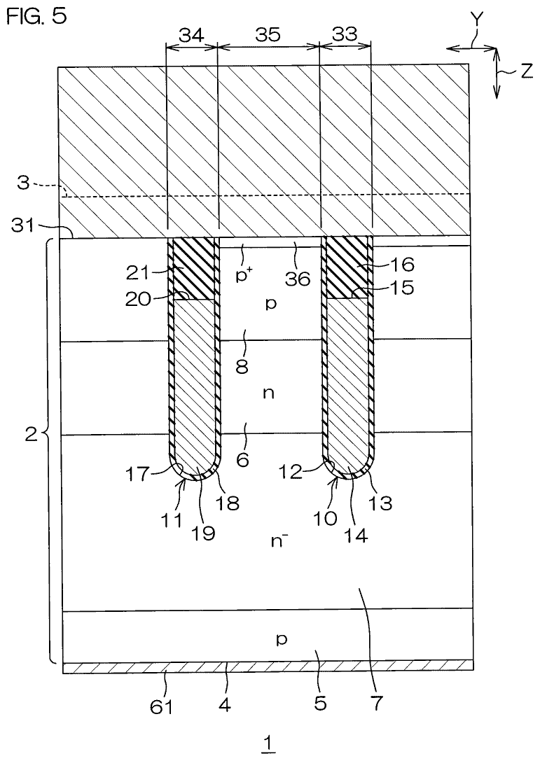

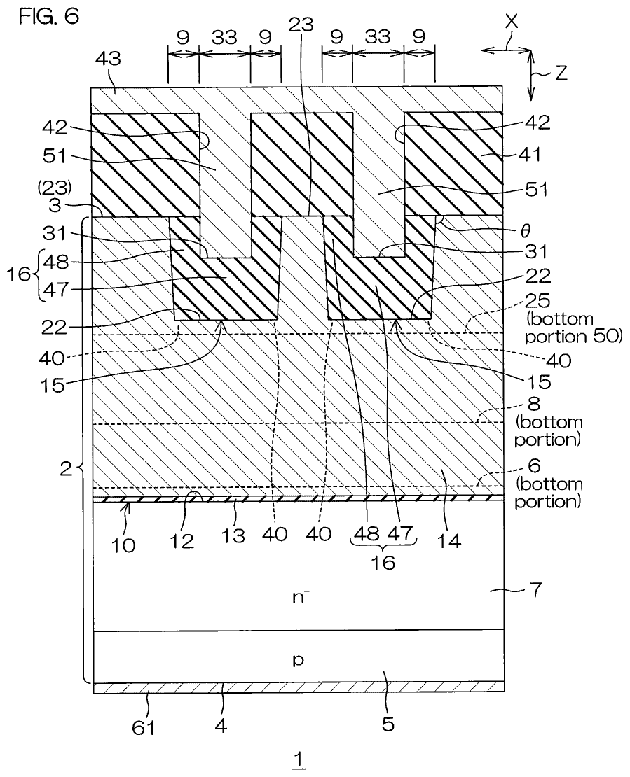

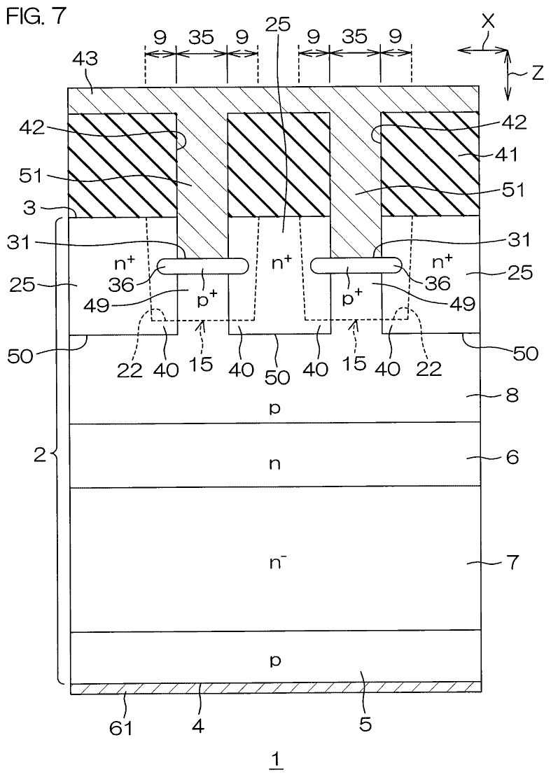

FIG. 4 is a schematic plan view of FIG. 3 as viewed from the first principal surface 3 of the chip 2. FIG. 5 is a cross-sectional view taken along line V-V illustrated in FIG. 4. FIG. 6 is a cross-sectional view taken along line VI-VI illustrated in FIG. 4. FIG. 7 is a cross-sectional view taken along line VII-VII illustrated in FIG. 4. FIGS. 5 to 7 also illustrate a structure on the first principal surface 3 of the chip 2.

In this preferred embodiment, the semiconductor device 1 has a basic form including a trench-gate type IGBT (Insulated Gate Bipolar Transistor). Referring to FIGS. 1 to 7, the semiconductor device 1 includes the chip 2 of an n⁻-type. In this preferred embodiment, the chip 2 is constituted of a silicon monocrystal substrate of the n⁻-type. The silicon monocrystal substrate is formed by using a semiconductor wafer of the n⁻-type silicon monocrystal manufactured through an FZ (Floating Zone) method. The chip 2 may be referred to as a semiconductor chip or a semiconductor layer.

The chip 2 has the first principal surface 3 on one side and a second principal surface 4 on the other side. A thickness of the chip 2 may be 50 μm or more and 300 μm or less. The thickness of the chip 2 may be 50 μm or more and 100 μm or less, 100 μm or more and 150 μm or less, 150 μm or more and 200 μm or less, 200 μm or more and 250 μm or less, or 250 μm or more and 300 μm or less.

A collector region 5 of a p-type is formed in a surface layer portion of the second principal surface 4. A charge storage region 6 of an n-type is formed in a surface portion of the first principal surface 3. The charge storage region 6 is formed in the first principal surface 3 side with an interval from the collector region 5.

In the chip 2, a drift region 7 of the n⁻-type is formed in a region between the collector region 5 and the charge storage region 6. The drift region 7 is formed by a region positioned between the collector region 5 and the charge storage region 6 in the chip 2. A body region 8 of the p-type is formed in a surface portion of the charge storage region 6. A plurality of trench gate electrode structures 10 and a plurality of trench emitter electrode structures 11 are formed in the surface portion of the first principal surface 3 at intervals.

Only the single trench gate electrode structure 10 and the single trench emitter electrode structure 11 that are adjacent to each other are shown in FIGS. 1 to 7. A structure of the semiconductor device 1 will be hereinafter described while paying attention to the structure of the single trench gate electrode structure 10 and that of the single trench emitter electrode structure 11.

The trench gate electrode structure 10 and the trench emitter electrode structure 11 extend as a band along an arbitrary first direction X in plan view. The trench gate electrode structure 10 and the trench emitter electrode structure 11 are formed at an interval along a second direction Y intersecting the first direction X.

More specifically, the term “plan view” denotes a plan view seen from a normal direction Z to the first principal surface 3 (hereinafter, referred to simply as “normal direction Z”). More specifically, the second direction Y is a direction perpendicular to the first direction X. The first direction X and the second direction Y are each also a tangential direction to the first principal surface 3.

A trench pitch PO between the trench gate electrode structure 10 and the trench emitter electrode structure 11 may be 0.1 μm or more and less than 0.6 μm. The trench pitch PO may be 0.1 μm or more and 0.2 μm or less, 0.2 μm or more and 0.3 μm or less, 0.3 μm or more and 0.4 μm or less, 0.4 μm or more and 0.5 μm or less, or 0.5 μm or more and less than 0.6 μm. The trench pitch PO is preferably 0.2 μm or more and 0.4 μm or less (for example, about 0.25 μm).

The trench gate electrode structure 10 includes a gate trench 12, a gate insulating layer 13, a gate electrode layer 14, a plurality of gate electrode recess portions 15 (space regions), and a plurality of gate covering insulating layers 16. The gate trench 12 passes through the body region 8 and the charge storage region 6 from the first principal surface 3 and reaches the drift region 7.

A depth of the gate trench 12 may be 2.0 μm or more and 4.0 μm or less. The depth of the gate trench 12 may be 2.0 μm or more and 2.5 μm or less, 2.5 μm or more and 3.0 μm or less, 3.0 μm or more and 3.5 μm or less, or 3.5 μm or more and 4.0 μm or less. The depth of the gate trench 12 is preferably 2.5 μm or more and 3.5 μm or less (for example, about 3.0 μm).

A second-direction width of the gate trench 12 may be 0.5 μm or more and 1.5 μm or less. The second-direction width of the gate trench 12 may be 0.5 μm or more and 0.75 μm or less, 0.75 μm or more and 1.0 μm or less, 1.0 μm or more and 1.25 μm or less, or 1.25 μm or more and 1.5 μm or less. The second-direction width of the gate trench 12 is preferably 0.5 μm or more and 1.0 μm or less (for example, about 0.75 μm).

The gate insulating layer 13 may be formed of silicon oxide. The gate insulating layer 13 is formed as a film along an inner wall of the gate trench 12. The gate insulating layer 13 defines a recessed space in the gate trench 12.

The gate electrode layer 14 may be formed of conductive polysilicon. The gate electrode layer 14 is controlled by a gate voltage. The gate electrode layer 14 is embedded in the gate trench 12 across the gate insulating layer 13. More specifically, the gate electrode layer 14 is embedded in the recessed space defined by the gate insulating layer 13 in the gate trench 12. An upper end portion of the gate electrode layer 14 is positioned on the first principal surface 3 side with respect to a bottom portion of the body region 8.

In this preferred embodiment, the plurality of gate electrode recess portions 15 are formed in the principal surface of the gate electrode layer 14 at intervals along the first direction X. As a result, the upper end portion of the gate electrode layer 14 has an uneven structure including the plurality of gate electrode recess portions 15.

An interval between the plurality of gate electrode recess portions 15 adjacent to each other may be more than 0 μm and 10 μm or less. The interval between the plurality of gate electrode recess portions 15 adjacent to each other is also a width in the first direction X of a part sandwiched between the two gate electrode recess portions 15 adjacent to each other in the gate electrode layer 14. The interval between the plurality of gate electrode recess portions 15 adjacent to each other may be more than 0 μm and 2 μm or less, 2 μm or more and 4 μm or less, 4 μm or more and 6 μm or less, 6 μm or more and 8 μm or less, or 8 μm or more and 10 μm or less.

In this preferred embodiment, side walls of each gate electrode recess portion 15 are formed by the gate insulating layer 13 and the gate electrode layer 14. A bottom wall 22 of each gate electrode recess portion 15 is formed by the gate electrode layer 14. Referring to FIGS. 6 and 7, the bottom wall 22 of each gate electrode recess portion 15 is positioned in a region between the first principal surface 3 and a bottom portion 50 of an emitter region 25 (described later) in the normal direction Z.

Referring to FIG. 6, each gate electrode recess portion 15 is formed in a tapered shape having a bottom area smaller than an opening area. An angle θ formed by the principal surface of the gate electrode layer 14 and the side wall of the gate electrode recess portion 15 in the gate electrode layer 14 may be more than 90° and 105° or less (for example, about) 102°.

The plurality of gate covering insulating layers 16 are embedded in the upper end portion of the gate electrode layer 14 in the gate trench 12. More specifically, the gate covering insulating layer 16 is embedded independently for each gate electrode recess portion 15. Each gate covering insulating layer 16 is exposed from an opening of the gate trench 12.

The trench emitter electrode structure 11 includes an emitter trench 17, an emitter insulating layer 18, an emitter electrode layer 19, an emitter electrode recess portion 20, and an emitter covering insulating layer 21. The emitter trench 17 penetrates the body region 8 and the charge storage region 6 from the first principal surface 3 and reaches the drift region 7.

A depth of the emitter trench 17 may be 2.0 μm or more and 4.0 μm or less. The depth of the emitter trench 17 may be 2.0 μm or more and 2.5 μm or less, 2.5 μm or more and 3.0 μm or less, 3.0 μm or more and 3.5 μm or less, or 3.5 μm or more and 4.0 μm or less. The depth of the emitter trench 17 is preferably 2.5 μm or more and 3.5 μm or less (for example, about 3.0 μm). Preferably, the depth of the emitter trench 17 is substantially equal to the depth of the gate trench 12.

A second-direction width of the emitter trench 17 may be 0.5 μm or more and 1.5 μm or less. The second-direction width of the emitter trench 17 may be 0.5 μm or more and 0.75 μm or less, 0.75 μm or more and 1.0 μm or less, 1.0 μm or more and 1.25 μm or less, or 1.25 μm or more and 1.5 μm or less. The second-direction width of the emitter trench 17 is preferably 0.5 μm or more and 1.0 μm or less (for example, about 0.75 μm). Preferably, the second-direction width of the emitter trench 17 is substantially equal to the second-direction width of the gate trench 12.

The emitter insulating layer 18 may be formed of silicon oxide. The emitter insulating layer 18 is formed as a film along an inner wall surface of the emitter trench 17. The emitter insulating layer 18 defines a recessed space in the emitter trench 17.

The emitter electrode layer 19 may be formed of conductive polysilicon. The emitter electrode layer 19 is controlled by an emitter voltage. The emitter voltage has a voltage value less than a gate voltage. The emitter voltage may be a reference voltage (for example, ground voltage). The emitter electrode layer 19 is embedded in the emitter trench 17 across the emitter insulating layer 18. More specifically, the emitter electrode layer 19 is embedded in the recessed space defined by the emitter insulating layer 18 in the emitter trench 17.

In this preferred embodiment, the emitter electrode recess portion 20 is formed such as to dig down substantially the entirety of a principal surface of the emitter electrode layer 19. In other words, the emitter electrode layer 19 is embedded to a halfway portion in the depth direction of the recessed space defined by the emitter insulating layer 18.

In this preferred embodiment, side walls of the emitter electrode recess portion 20 are formed by the emitter insulating layer 18. A bottom wall of the emitter electrode recess portion 20 is formed by the emitter electrode layer 19. The bottom wall of the emitter electrode recess portion 20 may be positioned in the region between the first principal surface 3 and the bottom portion 50 of the emitter region 25 (described later) in the normal direction Z or may be positioned in a portion deeper than the bottom portion of the emitter region 25. That is, an upper end portion of the emitter electrode layer 19 is positioned on the first principal surface 3 side with respect to the bottom portion 50 of the emitter region 25. In the normal direction Z, a depth of the emitter electrode recess portion 20 may be approximately equal to a depth of the gate electrode recess portion 15.

The emitter covering insulating layer 21 is embedded in an upper surface of the emitter electrode layer 19 in the emitter trench 17. More specifically, the emitter covering insulating layer 21 is embedded in the emitter electrode recess portion 20. Thus, the emitter covering insulating layer 21 seals the emitter electrode layer 19. The emitter covering insulating layer 21 is exposed from an opening of the emitter trench 17.

The emitter region 25 (first impurity region) of an n⁺-type is formed in a region along the side wall of the gate trench 12 in a surface portion of the body region 8. More specifically, a plurality of the emitter regions 25 are formed, in the first direction X, along a side wall on one side and along a side wall on the other side of the gate trench 12. The plurality of emitter regions 25 are each formed as a band extending along the first direction X. The emitter region 25 is in contact with the side wall of the gate trench 12. The emitter region 25 is in contact also with a side wall of the emitter trench 17.

The emitter region 25, the body region 8, the charge storage region 6, and the drift region 7 are formed in that order from the first principal surface 3 toward the second principal surface 4 side in the region along the side wall of the gate trench 12 in the surface portion of the first principal surface 3. In the body region 8, a channel CH of the IGBT is formed in a region facing the gate electrode layer 14 across the gate insulating layer 13.

Referring to FIGS. 3, 4, 6, and 7, a plurality of contact trenches 31 are formed in the surface portion of the first principal surface 3. The plurality of contact trenches 31 are formed at intervals along the first direction X. Each of the plurality of contact trenches 31 is formed as a band extending along the second direction Y. A first-direction width of each contact trench 31 is smaller than the second-direction width of the gate trench 12. The first-direction width of each contact trench 31 may be, for example, 0.3 μm or more and 1.0 μm or less.

More specifically, each contact trench 31 penetrates the side walls of the gate trench 12 from an inner region of the corresponding gate covering insulating layer 16 and is led out to the surface portion of the first principal surface 3. In this preferred embodiment, each contact trench 31 penetrates the side wall on one side and the side wall on the other side of the gate trench 12 from the inner region of the gate covering insulating layer 16 in the first direction X. The first-direction width of each contact trench 31 is smaller than a first-direction width of the corresponding gate covering insulating layer 16.

Each contact trench 31 includes a first intersection region 33 intersecting the gate electrode layer 14 in plan view. In the first intersection region 33, side walls and a bottom wall of each contact trench 31 are formed by the gate covering insulating layer 16.

Each contact trench 31 includes a second intersection region 34 intersecting the emitter electrode layer 19 in plan view. In the second intersection region 34, the side wall and the bottom wall of each contact trench 31 are formed by the emitter covering insulating layer 21.

Each contact trench 31 further includes a contact region 35 led out from the first intersection region 33 to the outside of the gate trench 12. The contact region 35 may be referred to as a connection region that connects the first intersection region 33 and the second intersection region 34 in a region between the gate trench 12 and the emitter trench 17 in plan view. In the contact region 35, the bottom wall of each contact trench 31 is formed by the body region 8, and a side wall of each contact trench 31 is formed by the emitter region 25. That is, the emitter region 25 is exposed on the side wall of the contact trench 31 in the contact region 35.

Each contact trench 31 further includes a lead-out portion 32 led out from the side wall on one side of the emitter trench 17 to the outside. Each lead-out portion 32 penetrates the side wall on one side of the emitter trench 17 from the surface portion of the first principal surface 3 and reaches the inside of the emitter trench 17.

The side walls of each contact trench 31 are formed to be flush with each other in the first intersection region 33, the second intersection region 34, and the contact region 35. The bottom wall of each contact trench 31 is formed to be flush with each other in the first intersection region 33, the second intersection region 34, and the contact region 35.

In the first intersection region 33, the upper end portion of the gate electrode layer 14 is positioned on the first principal surface 3 side with respect to the bottom portion 50 of the emitter region 25. As a result, with reference to FIGS. 6 and 7, the emitter region 25 has a facing portion 40 facing the gate electrode layer 14 via the gate insulating layer 13 below a peripheral portion 9 on both sides of the first intersection region 33 in the first direction X.

The gate electrode layer 14 has an electrode uneven structure formed by the first intersection region 33 of each contact trench 31 and the gate electrode recess portion 15 formed in the peripheral portion 9 along the first direction X. A part of an upper surface of the gate electrode layer 14 (an upper surface 23 of the projection portion of the electrode uneven structure) is exposed between the adjacent contact trenches 31.

The gate electrode recess portion 15 is formed across the peripheral portion 9 on one side and the peripheral portion 9 on the other side of the first intersection region 33 in the first direction X. Thus, referring to FIGS. 6 and 7, the gate covering insulating layer 16 includes a first portion 47 disposed in the first intersection region 33 and a second portion 48 disposed in each of the peripheral portion 9 on one side and the peripheral portion 9 on the other side in the first direction X with respect to the first portion 47.

The peripheral portion 9 of the first intersection region 33 may be, for example, a region from the side wall of the contact trench 31 to the side wall of the gate electrode recess portion 15. The peripheral portion 9 may be, for example, a region in a range of 0.05 μm or more and 0.5 μm or less from a side wall of the first intersection region 33. That is, in this preferred embodiment, the side walls of the gate electrode recess portion 15 are formed at an interval of 0.05 μm or more and 0.5 μm or less on both sides of the contact trench 31 in the first direction X.

The plurality of contact trenches 31 are arbitrarily arranged. The plurality of contact trenches 31 may be formed at equal intervals along the first direction X. The plurality of contact trenches 31 may be formed at unequal intervals along the first direction X.

A contact region 36 of a p⁺-type is formed in a region along the bottom wall of each contact trench 31 in the body region 8. The contact region 36 may be formed in a region along the bottom wall and the side walls of each contact trench 31 in the body region 8.

The contact region 36 has an exposed surface exposed from the bottom wall of the contact trench 31. The exposed surface of the contact region 36 is formed in a region between the first principal surface 3 and the bottom portion of the body region 8. More specifically, the exposed surface of the contact region 36 is formed in a region between the first principal surface 3 and the bottom portion 50 of the emitter region 25. In this preferred embodiment, the body region 8 has a body region projection portion 49 selectively projecting toward the first principal surface 3 side along the contact trench 31. The contact region 36 is formed at a tip end portion of the body region projection portion 49. The body region projection portion 49 is sandwiched between the emitter regions 25 in the first direction X.

FIGS. 1 to 3 illustrate an example in which the contact region 36 is formed shallow on a bottom surface of the contact trench 31 by one ion implantation. However, the contact region 36 may be formed deeper by adjusting the number of times of ion implantation or by adjusting the energy of ion implantation. For example, the contact region 36 may be formed deeper than the bottom portion 50 of the emitter region 25.

An interlayer insulating layer 41 is formed on the first principal surface 3. The interlayer insulating layer 41 covers the trench gate electrode structure 10 and the trench emitter electrode structure 11. The interlayer insulating layer 41 covers the gate covering insulating layer 16 exposed from the gate trench 12 and the emitter covering insulating layer 21 exposed from the emitter trench 17.

The interlayer insulating layer 41 may be formed of silicon oxide or silicon nitride. The interlayer insulating layer 41 may have a laminated structure including an oxide film (SiO₂ film) and a nitride film (SiN film). The oxide film (SiO₂ film) may include an NSG (Nondoped Silicon Glass) film that does not contain impurities and/or a PSG (Phosphorus Silicon Glass) film that contains phosphorus.

The interlayer insulating layer 41 may have a laminated structure including an NSG film and a PSG film laminated in that order from the first principal surface 3. A thickness of the NSG film may be 2000 Å or more and 8000 Å or less (for example, about 5000 Å). A thickness of the PSG film may be 2000 Å or more and 6000 Å or less (for example, about 4000 Å).

A plurality of contact holes 42 are formed in the interlayer insulating layer 41. Each of the plurality of contact holes 42 communicates with the corresponding contact trench 31. In other words, the plurality of contact holes 42 are formed at intervals along the first direction X and are each formed as a band extending along the second direction Y.

The plurality of contact holes 42 pass through the interlayer insulating layer 41 and communicate with the corresponding contact trenches 31, respectively. As a result, the plurality of contact holes 42 each form one emitter contact trench 31, 42 with the corresponding contact trench 31.

A first-direction width of each contact hole 42 may be equal to or larger than the first-direction width of each contact trench 31. That is, the first-direction width of each contact hole 42 may be equal to the first-direction width of each contact trench 31 or may exceed the first-direction width of each contact trench 31. When the first-direction width of each contact hole 42 exceeds the first-direction width of each contact trench 31, an inner wall of each contact hole 42 may surround an inner wall of the corresponding contact trench 31.

The arrangement of the plurality of contact holes 42 is arbitrary and is adjusted according to the arrangement of the contact trenches 31. The plurality of contact holes 42 may be formed at equal intervals along the first direction X. The plurality of contact holes 42 may be formed at unequal intervals along the first direction X.

An emitter principal surface electrode layer 43 is formed on the interlayer insulating layer 41. The emitter principal surface electrode layer 43 enters the contact hole 42 and the contact trench 31 (that is, the emitter contact trench 31, 42) from above the interlayer insulating layer 41. The emitter principal surface electrode layer 43 may include, for example, a laminated structure of a barrier layer of titanium or the like and an electrode layer of tungsten or the like. In this preferred embodiment, the plurality of emitter contact electrode layers 51 are formed by parts of the emitter principal surface electrode layer 43 positioned in the plurality of contact trenches 31. As a result, a structure in which the plurality of emitter contact electrode layers 51 are embedded in a surface portion of the chip 2 is formed.

Each of the plurality of emitter contact electrode layers 51 has an arrangement and a shape corresponding to the arrangement and the shape of the plurality of contact trenches 31. In other words, the plurality of emitter contact electrode layers 51 are formed at intervals along the first direction X and are each formed as a band extending along the second direction Y.

Each emitter contact electrode layer 51 faces the gate electrode layer 14 across the gate covering insulating layer 16 in the normal direction Z and the first direction X in the first intersection region 33 intersecting the gate electrode layer 14 in plan view. Each emitter contact electrode layer 51 is insulated from the gate electrode layer 14 by the gate covering insulating layer 16. A first-direction width of each of the emitter contact electrode layers 51 is smaller than a first-direction width of the gate trench 12.

Each emitter contact electrode layer 51 penetrates the side wall of the gate trench 12 from an inner region of the corresponding gate covering insulating layer 16 and is extended to the surface portion of the first principal surface 3. In this preferred embodiment, each emitter contact electrode layer 51 penetrates the side wall on one side and the side wall on the other side of the gate trench 12 from the inner region of the gate covering insulating layer 16 in the second direction Y. The first-direction width of each emitter contact electrode layer 51 is smaller than the first-direction width of the corresponding gate covering insulating layer 16.

Each emitter contact electrode layer 51 faces the emitter electrode layer 19 across the emitter covering insulating layer 21 in the normal direction Z and the first direction X in the second intersection region 34 intersecting the emitter electrode layer 19 in plan view. Each emitter contact electrode layer 51 is insulated from the emitter electrode layer 19 by the emitter covering insulating layer 21. The first-direction width of each of the emitter contact electrode layers 51 is smaller than a first-direction width of the emitter trench 17.

In the contact region 35, each emitter contact electrode layer 51 is connected to the body region 8 (the contact region 36) exposed from the bottom wall of the contact trench 31 and is connected to the emitter region 25 exposed from the side wall of the contact trench 31.

A collector electrode layer 61 is formed on the second principal surface 4 of the chip 2. The collector electrode layer 61 is connected to the collector region 5. Although not illustrated, a gate principal surface electrode layer that has the same structure as the emitter principal surface electrode layer 43 may be formed on the interlayer insulating layer 41. The gate principal surface electrode layer may be electrically connected to the gate electrode layer 14 through a gate contact hole formed in the interlayer insulating layer 41.

### <<Description of Method for Manufacturing Semiconductor Device 1>>

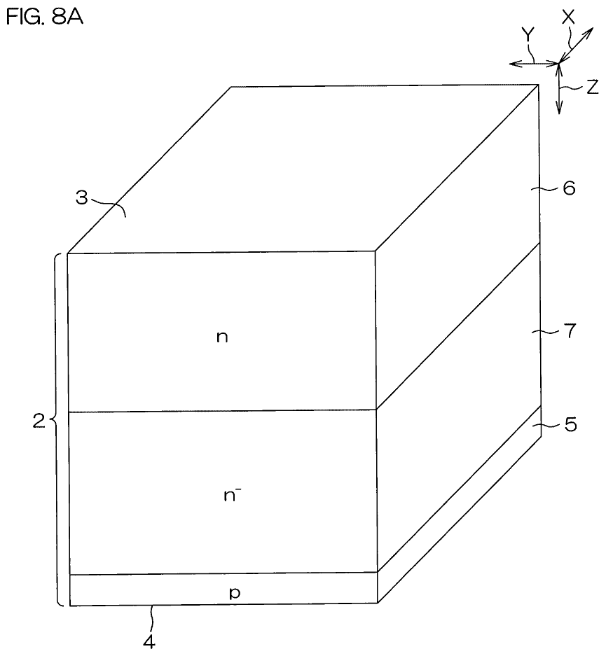

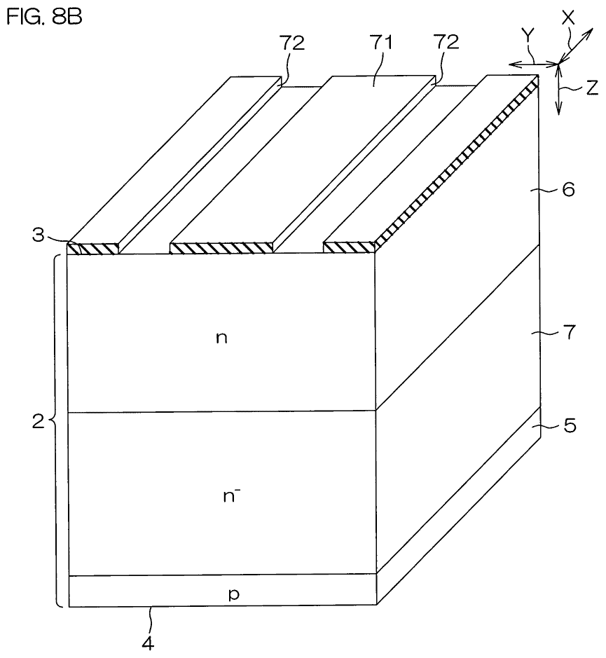

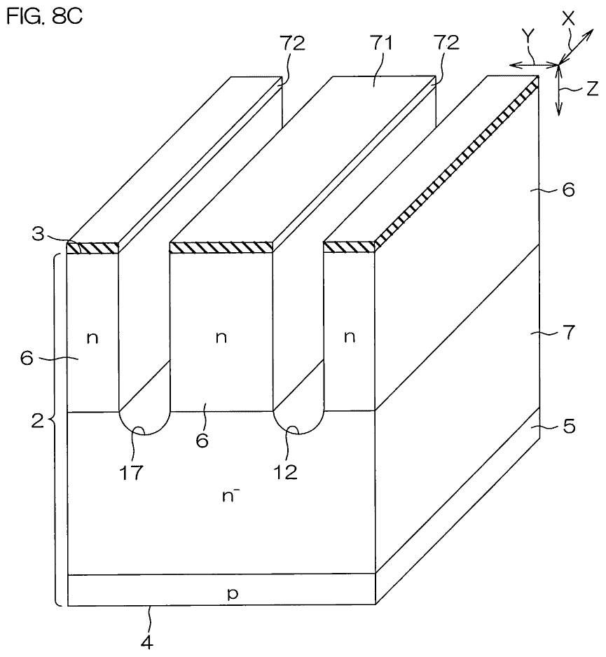

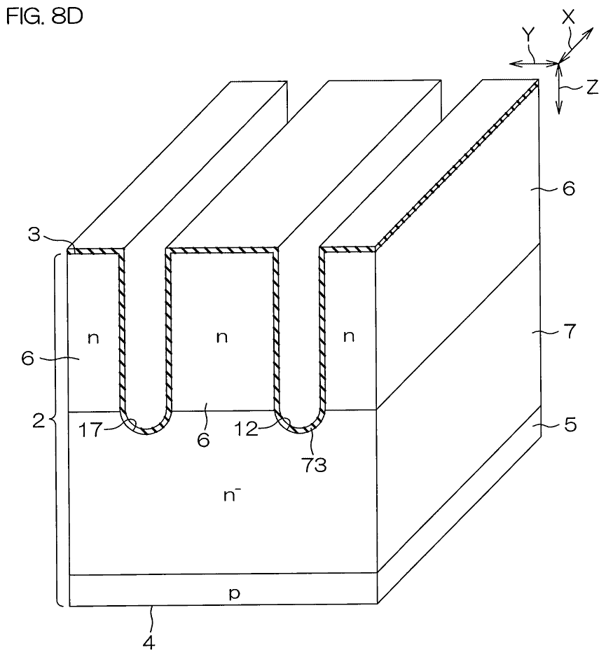

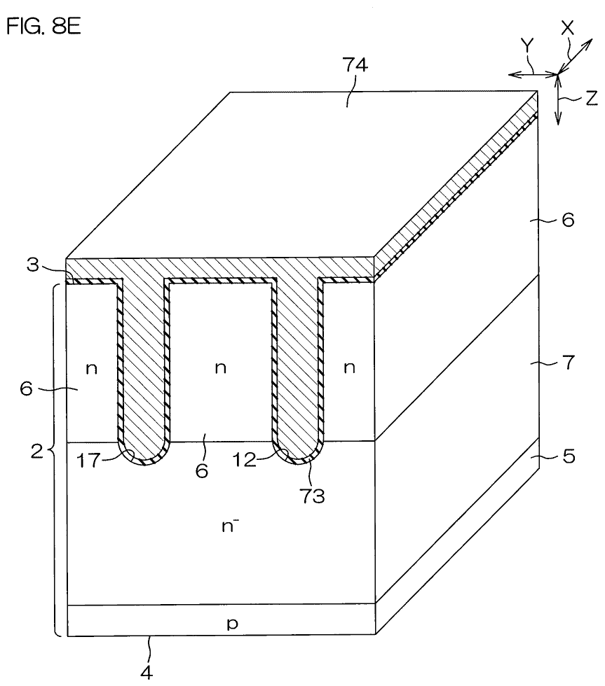

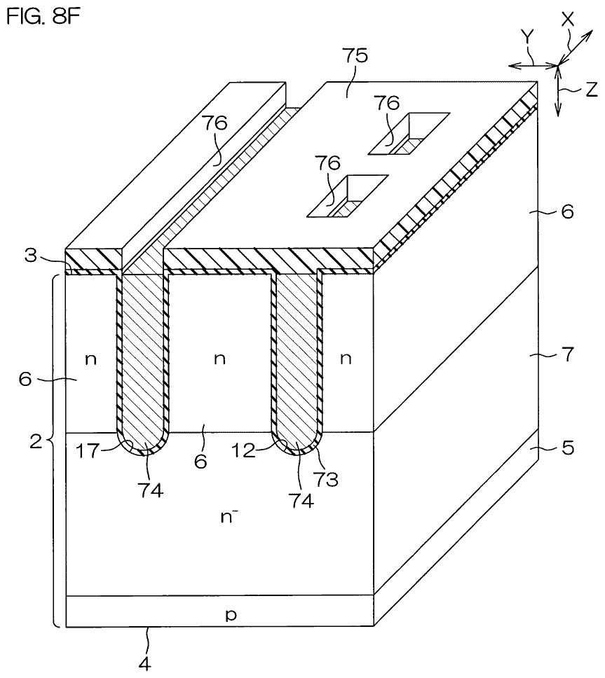

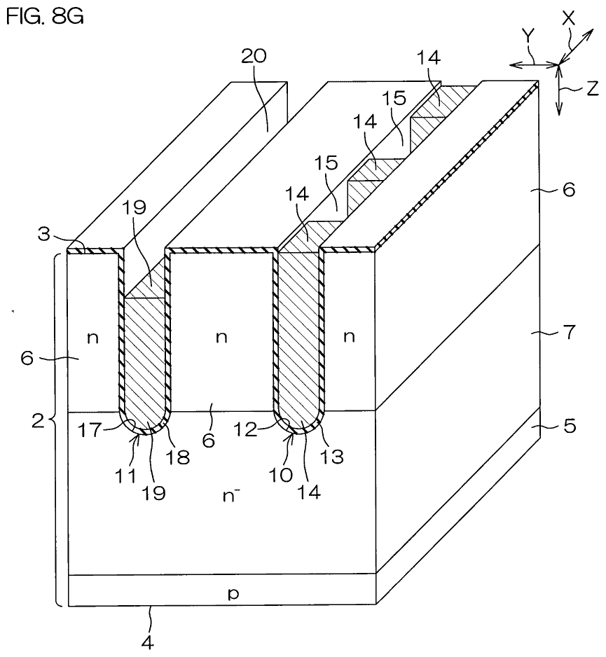

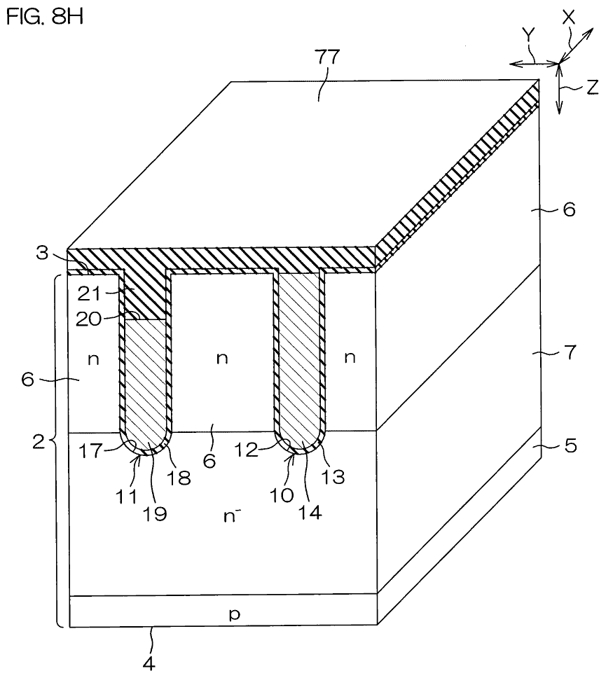

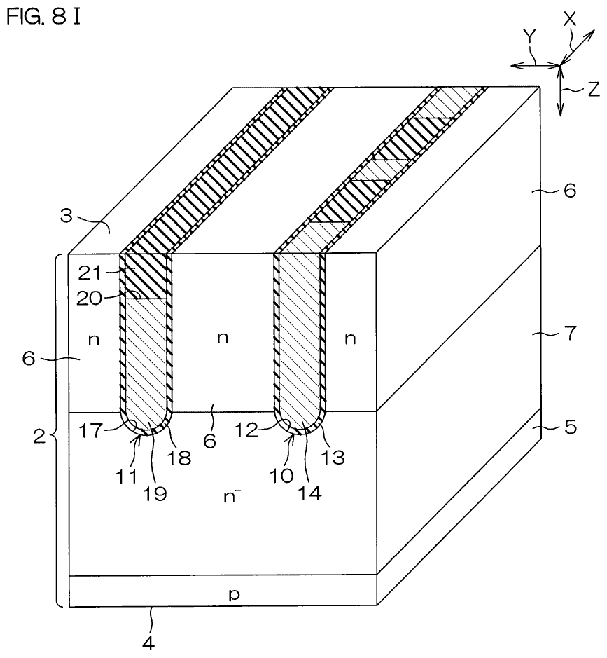

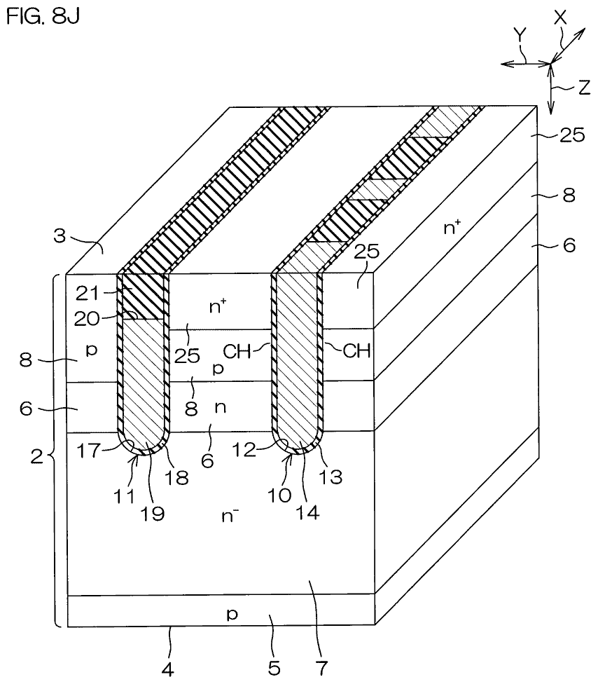

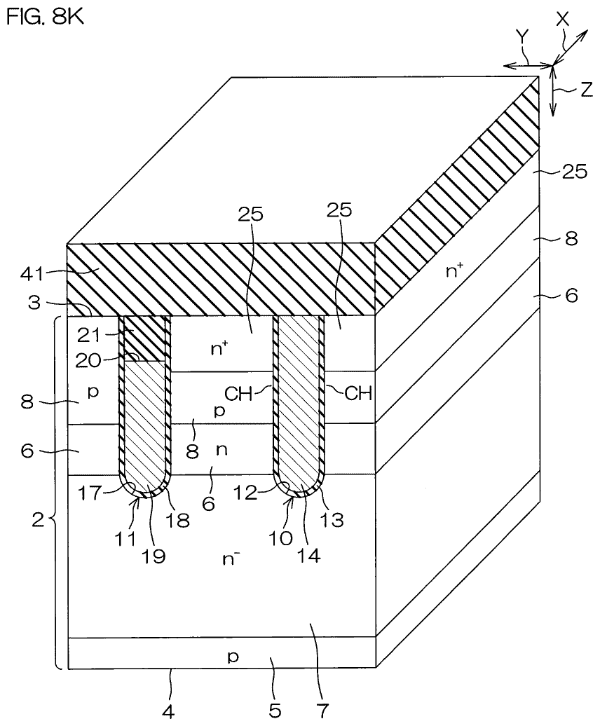

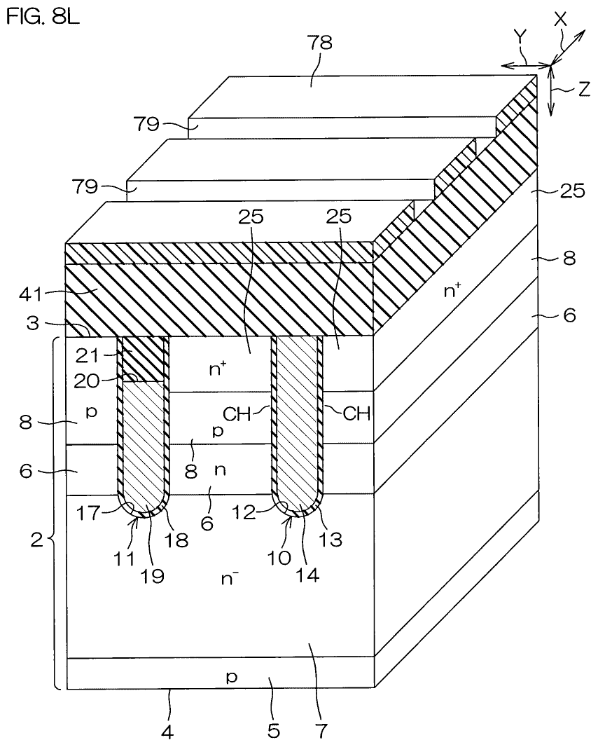

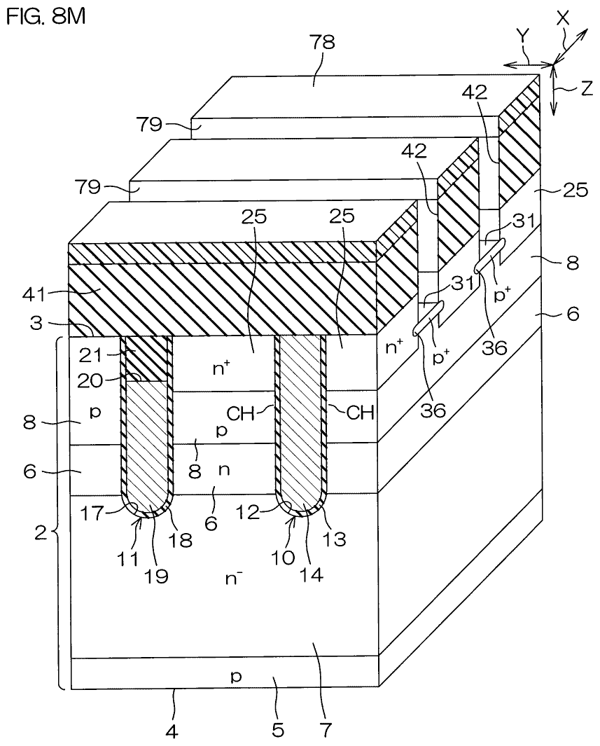

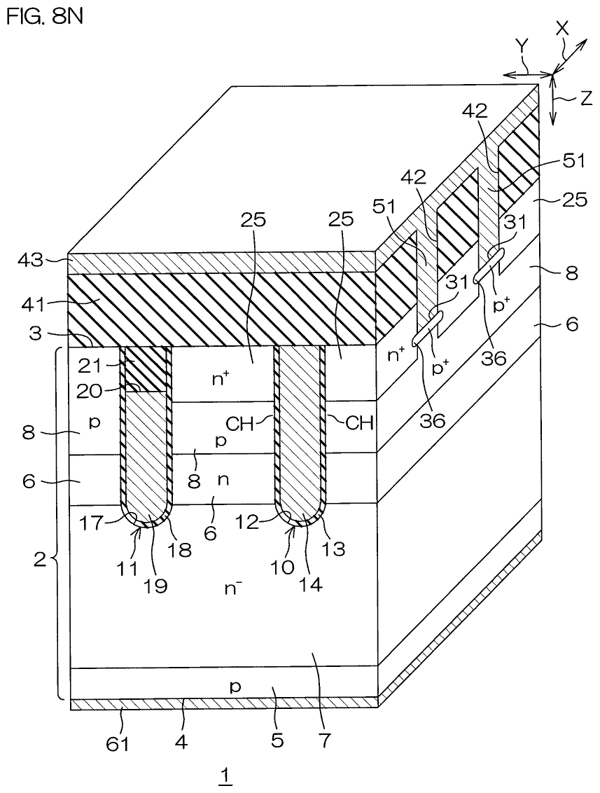

FIGS. 8A to 8N are diagrams illustrating an example of a method of manufacturing the semiconductor device 1. FIG. 8A to FIG. 8N are each also a cross-sectional perspective view of a part corresponding to FIG. 1.

Referring to FIG. 8A, first, the n-type chip 2 is prepared. Next, the p-type collector region 5 and the n-type charge storage region 6 are formed in the chip 2. The collector region 5 is formed by introducing a p-type impurity into the second principal surface 4 of the chip 2. The collector region 5 may be formed in the surface portion of the second principal surface 4 of the chip 2 by an ion implantation method through an ion implantation mask (not shown).

The charge storage region 6 is formed by introducing an n-type impurity into the first principal surface 3. The charge storage region 6 may be formed in the surface portion of the first principal surface 3 by the ion implantation method through an ion implantation mask (not shown).

Next, referring to FIG. 8B, a mask 71 having a predetermined pattern is formed on the first principal surface 3. The mask 71 has a plurality of openings 72 that expose regions in which the gate trench 12 and the emitter trench 17 are to be formed.

Next, referring to FIG. 8C, unnecessary portions of the chip 2 are removed from the first principal surface 3. The unnecessary portions of the chip 2 may be removed by an etching method (for example, wet etching method) through the mask 71. Accordingly, the gate trench 12 and the emitter trench 17 are formed. Thereafter, the mask 71 is removed.

Next, referring to FIG. 8D, a base insulating layer 73 that is to be a base of both the gate insulating layer 13 and the emitter insulating layer 18 is formed such as to cover the first principal surface 3. The base insulating layer 73 may be formed by an oxidation treatment method onto the first principal surface 3.

The oxidation treatment method may be a thermal oxidation treatment method or a wet oxidation treatment method. The base insulating layer 73 may include silicon oxide. The base insulating layer 73 may be formed by a CVD (chemical vapor deposition) method instead of the oxidation treatment method.

Next, referring to FIG. 8E, a base conductor layer 74 that is to be a base of both the gate electrode layer 14 and the emitter electrode layer 19 is formed on the first principal surface 3. The base conductor layer 74 may be a conductive polysilicon layer. The base conductor layer 74 may be formed by a CVD method. The CVD method may be an LP-CVD (Low Pressure-CVD) method.

Next, unnecessary portions of the base conductor layer 74 are removed. The unnecessary portions of the base conductor layer 74 are removed until at least the base insulating layer 73 is exposed. The unnecessary portions of the base conductor layer 74 may be removed by the etching method (for example, wet etching method).

The unnecessary portions of the base conductor layer 74 may be removed by the etching method (for example, wet etching method) after a principal surface of the base conductor layer 74 is flattened by a CMP (Chemical Mechanical Polishing) method.

Next, referring to FIG. 8F, a mask 75 having a predetermined pattern is formed on the first principal surface 3. The mask 75 has a plurality of openings 76 that expose regions in which the gate electrode recess portion 15 and the emitter electrode recess portion 20 are to be formed.

Next, unnecessary portions of the gate electrode layer 14 and unnecessary portions of the emitter electrode layer 19 are removed. The unnecessary portions of the gate electrode layer 14 and the unnecessary portions of the emitter electrode layer 19 may be removed by the etching method (for example, wet etching method) through the mask 75. Thus, the gate electrode recess portion 15 and the emitter electrode recess portion 20 are formed.

Thereafter, referring to FIG. 8G, the mask 75 is removed. The gate electrode recess portion 15 and the emitter electrode recess portion 20 may be formed separately via different masks (not shown). That is, the gate electrode recess portion 15 and the emitter electrode recess portion 20 having different depths may be formed.

Next, referring to FIG. 8H, a base insulating layer 77 that is to be a base of the gate covering insulating layer 16 and the emitter covering insulating layer 21 is formed on the first principal surface 3. The base insulating layer 77 may include silicon oxide. The base insulating layer 77 may be formed by the CVD method. The CVD method may be an LP-CVD method.

Next, referring to FIG. 8I, unnecessary portions of the base insulating layer 77 are removed. The unnecessary portions of the base insulating layer 77 may be removed by the etching method (for example, wet etching method). Thus, the gate covering insulating layer 16 and the emitter covering insulating layer 21 are formed.

In this step, the part with which the first principal surface 3 is covered in the base insulating layer 73 is also removed. As a result, the gate insulating layer 13 and the emitter insulating layer 18 are formed. Additionally, as a result, the trench gate electrode structure 10 and the trench emitter electrode structure 11 are formed.

Next, referring to FIG. 8J, the p-type body region 8 and the n⁺-type emitter region 25 are formed in the chip 2. The body region 8 is formed by introducing a p-type impurity into the first principal surface 3. The body region 8 may be formed in the surface portion of the first principal surface 3 by the ion implantation method through an ion implantation mask (not shown).

The emitter region 25 is formed by introducing an n-type impurity into the first principal surface 3. The emitter region 25 may be formed in the surface portion of the first principal surface 3 by the ion implantation method through an ion implantation mask (not shown).

Next, referring to FIG. 8K, the interlayer insulating layer 41 is formed on the first principal surface 3. The interlayer insulating layer 41 is formed on the first principal surface 3 such as to cover the trench gate electrode structure 10 and the trench emitter electrode structure 11. This step may include a step of forming an NSG film (for example, 5000 Å) and a PSG film (for example, 4000 Å) in that order on the first principal surface 3 by a CVD method.

Next, referring to FIG. 8L, a mask 78 having a predetermined pattern is formed on the interlayer insulating layer 41. The mask 78 has a plurality of openings 79 that expose regions in which the contact trenches 31 and the contact holes 42 are to be formed.

Next, referring to FIG. 8M, unnecessary portions of the interlayer insulating layer 41, unnecessary portions of the gate covering insulating layer 16, and unnecessary portions of the emitter covering insulating layer 21 are removed. The unnecessary portions of the interlayer insulating layer 41, etc., may be removed by an etching method (for example, a dry etching method) through the mask 78.

Additionally, in this step, after the unnecessary portions of the interlayer insulating layer 41 etc., are removed, unnecessary portions of the chip 2 are removed. The unnecessary portions of the chip 2 may be removed by the etching method (for example, dry etching method) through the mask 78.

Hence, the contact trenches 31 are formed in the first principal surface 3, and the contact holes 42 that communicate with the contact trenches 31 are formed in the interlayer insulating layer 41. Thereafter, the mask 78 is removed.

Next, the contact region 36 is formed in the surface portion of the first principal surface 3. More specifically, the contact region 36 is formed in a region along the bottom wall of the contact trench 31 in the surface portion of the body region 8. The contact region 36 may be formed in a region along the side wall and the bottom wall of the contact trench 31.

The contact region 36 is formed by introducing a p-type impurity into the contact trench 31. The contact region 36 may be introduced into the contact trench 31 by the ion implantation method through an ion implantation mask (not shown). As a result, the contact region 36 along the bottom wall of the contact trench 31 is formed.

The contact region 36 may be formed by introducing p-type impurities into the first principal surface 3 in the step of FIG. 8J. In this case, the contact region 36 may be formed at the surface portion of the first principal surface 3 by the ion implantation method through an ion implantation mask (not shown). Also in this step, the contact region 36 along the bottom wall of the contact trench 31 is formed.

Next, referring to FIG. 8N, the emitter principal surface electrode layer 43 is formed on the interlayer insulating layer 41. Then, the emitter contact electrode layer 51 is formed by the portion of the emitter principal surface electrode layer 43 that enters the contact trench 31. Also, the collector electrode layer 61 is formed on the second principal surface 4 of the chip 2. The semiconductor device 1 is formed through these steps mentioned above.

### <<Relationship Between Depth of Emitter Region 25 and Area of Channel Forming Region 102, 202>>

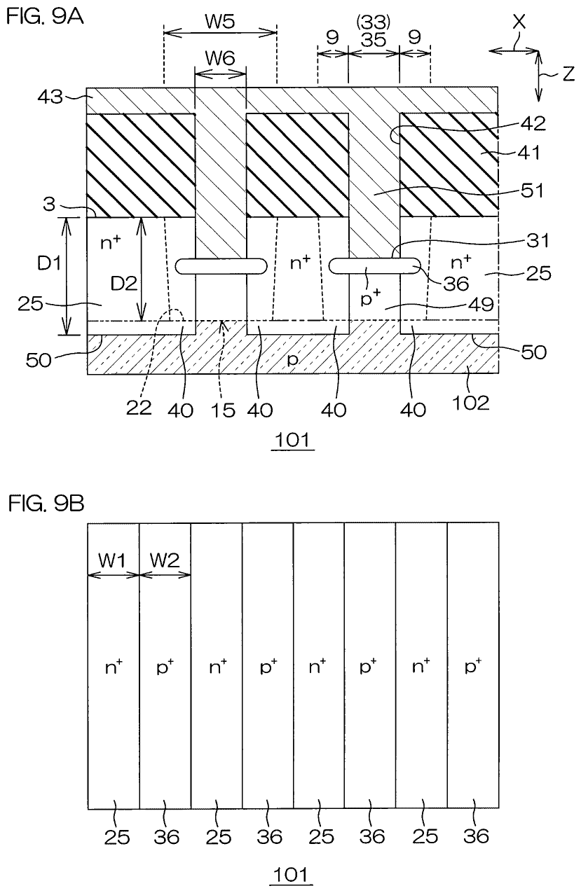

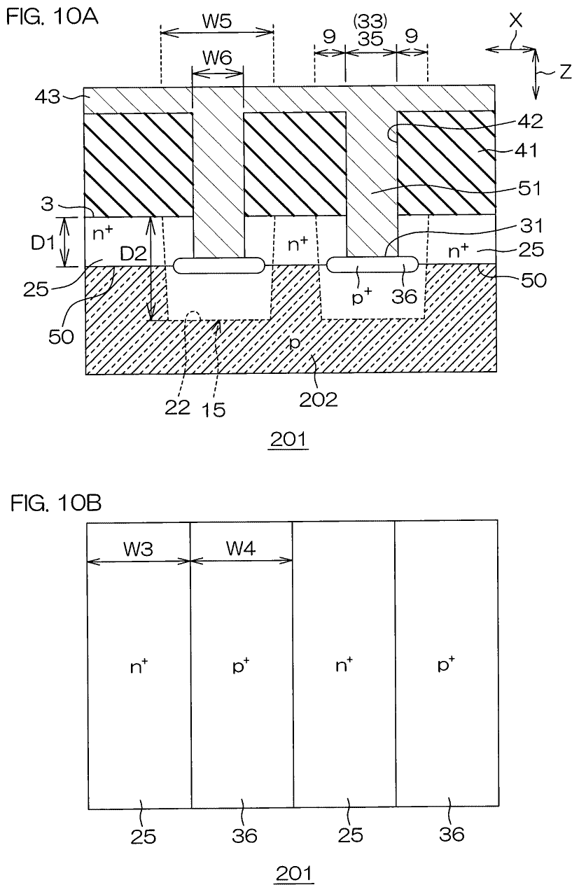

FIG. 9A is a diagram for explaining channel formation of a semiconductor device 101 according to Condition 1. FIG. 9B is a diagram for explaining an arrangement pattern of the emitter region 25 and the contact region 36 of the semiconductor device 101 according to Condition 1. FIG. 10A is a diagram for explaining channel formation of a semiconductor device 201 according to Condition 2. FIG. 10B is a diagram for explaining an arrangement pattern of the emitter region 25 and the contact region 36 of the semiconductor device 201 according to Condition 2. In the semiconductor device 101, 201, structures corresponding to the semiconductor device 1 shall be provided with the same reference signs and description thereof shall be omitted.

Referring to FIG. 9A, the semiconductor device 101 has the same structure as the semiconductor device 1. The emitter region 25 is formed deeper than the upper surface of the gate electrode layer 14 in the gate electrode recess portion 15 (a bottom wall 22 of the gate electrode recess portion 15). That is, the bottom portion 50 of the emitter region 25 is positioned on the second principal surface 4 side (the opposite side of the first principal surface 3) with respect to the upper surface of the gate electrode layer 14 (the bottom wall 22 of the gate electrode recess portion 15) in the peripheral portions 9 on both sides of the first intersection region 33 in the first direction X. A depth D1 of the emitter region 25 from the first principal surface 3 is larger than a depth D2 of the gate electrode recess portion 15 from the first principal surface 3 (D1>D2). As a result, the emitter region 25 has the facing portion 40 facing the gate electrode layer 14 via the gate insulating layer 13 below the peripheral portions 9 on both sides of the first intersection region 33 in the first direction X.

Referring to FIG. 9B, a width W1 of the emitter region 25 in the first direction X is, for example, 1.0 μm or less, and preferably 0.5 μm or more and 1.0 μm or less. A width W2 of the contact region 36 in the first direction X may be equal to the first-direction width of the contact trench 31 described above or may be slightly wider than the first-direction width of the contact trench 31.

Referring to FIG. 10A, in the semiconductor device 201, the emitter region 25 is formed shallower than the upper surface of the gate electrode layer 14 in the gate electrode recess portion 15 (the bottom wall 22 of the gate electrode recess portion 15). That is, the bottom portion 50 of the emitter region 25 is positioned on the first principal surface 3 side with respect to the upper surface of the gate electrode layer 14 (the bottom wall 22 of the gate electrode recess portion 15) in the peripheral portions 9 on both sides of the first intersection region 33 in the first direction X. The depth D1 of the emitter region 25 from the first principal surface 3 is smaller than the depth D2 of the gate electrode recess portion 15 from the first principal surface 3 (D1<D2). As a result, in the semiconductor device 201, the facing portion 40 illustrated in FIG. 9A does not exist, and the emitter region 25 does not face the gate electrode layer 14 below the peripheral portions 9 on both sides of the first intersection region 33 in the first direction X.

Referring to FIG. 10B, a width W3 of the emitter region 25 in the first direction X exceeds, for example, 1.0 μm. A width W4 of the contact region 36 in the first direction X may be equal to the first-direction width of the contact trench 31 described above or may be slightly wider than the first-direction width of the contact trench 31.

Referring to FIGS. 9A and 10A, a first-direction width W5 of the gate electrode recess portion 15 is set to be wider than a first-direction width W6 of the contact trench 31. This is to secure a margin in consideration of positional deviation during patterning of the mask 78 for forming the contact trench 31 (see FIGS. 8L and 8M). By securing this margin, the emitter contact electrode layer 51 falls within the range of the gate covering insulating layer 16, and the emitter contact electrode layer 51 is reliably insulated from the gate electrode layer 14 by the gate covering insulating layer 16. A short circuit between the emitter and the gate is thereby avoided. That is, a dig-in width of the gate electrode layer 14 (the width W5 of the gate electrode recess portion 15) needs to be made wider than a contact dimension of the emitter contact electrode layer 51 (the width W6 of the contact trench 31).

Therefore, as in the semiconductor device 201 in FIG. 10A, when the depth D1 of the emitter region 25 is smaller than the depth D2 of the gate electrode recess portion 15 (D1<D2), the lower region of the peripheral portion 9 becomes a region in which the emitter region 25 does not exist and the channel CH can be formed in this region, but a main current path cannot be formed. Therefore, in the semiconductor device 201, a region excluding a lower region of the gate electrode recess portion 15 in the body region 8 is a region in which the main current path can be formed in a channel forming region 202 where the channel CH can be formed, and the lower region of the gate electrode recess portion 15 results in a region in which it is difficult to form the main current path. As a result, a channel width tends to decrease, and the on-resistance tends to increase. In FIG. 10A, the channel forming region 202 is indicated by hatching including solid lines and broken lines.

In addition, as illustrated in FIG. 10B, there is a constraint that the width W3 of the emitter region 25 should be designed to be relatively wide in consideration of the etching margin. This is because if the width W3 of the emitter region 25 is too narrow, a portion facing the gate electrode layer 14 in the emitter region 25 is significantly reduced after the formation of the gate electrode recess portion 15.

On the other hand, as in the semiconductor device 101 in FIG. 9A, when the depth D1 of the emitter region 25 is larger than the depth D2 of the gate electrode recess portion 15 (D1>D2), the emitter region 25 also exists in the lower region of the peripheral portion 9, and a main current path can be formed in that region. Therefore, in the semiconductor device 101, an entire region in the first direction X of the body region 8 including the lower region of the gate electrode recess portion 15 is a channel forming region 102 where the main current path can be formed. As a result, the channel width can be made larger than that of the semiconductor device 201, and the on-resistance can be reduced. In FIG. 9A, the channel forming region 102 is indicated by hatching including solid lines and broken lines.

In addition, it becomes no longer necessary to consider the etching margin and the pattern of the gate electrode recess portion 15 when designing the width W1 of the emitter region 25. This is because, even after the formation of the gate electrode recess portion 15, the facing portion 40 of the emitter region 25 can be secured below the peripheral portion 9, thereby the channel forming region 102 having a sufficient channel width can be secured. Therefore, the width W1 of the emitter region 25 can be made narrower than the width W3 of the emitter region 25 of the semiconductor device 201.

### <<Relationship Between Depth of Emitter Region 25 and Characteristics of Semiconductor Device 101, 201>>

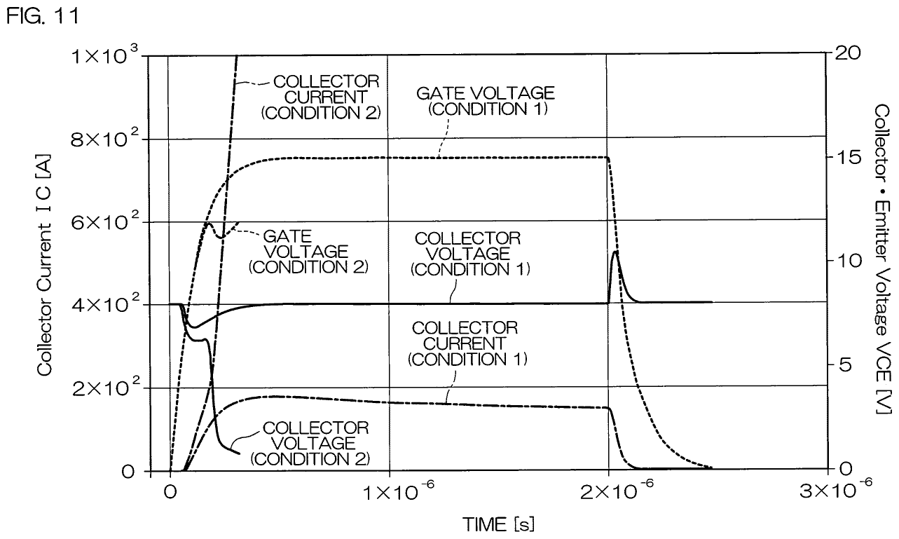

Next, the relationship between the depth of the emitter region 25 and the characteristics of the semiconductor device 101, 201 will be described with reference to FIGS. 11 to 14.

FIG. 11 is a graph in which short circuit waveforms of the semiconductor device 101 according to Condition 1 and the semiconductor device 201 according to Condition 2 are obtained by simulation. Referring to FIG. 11, the ordinate on the left side indicates a collector current IC [A], the ordinate on the right side indicates a collector-emitter voltage VCE [V], and the abscissa indicates time [s]. In FIG. 11, gate voltages according to Conditions 1 and 2 are indicated by the broken line plots, collector voltages according to Conditions 1 and 2 are indicated by the solid line plots, and collector currents according to Conditions 1 and 2 are indicated by the alternate long and short dashed line plots.

With reference to the gate voltage, the collector voltage, and the collector current according to Condition 1, it was observed that the semiconductor device 101 does not exceed the steady value from the rise of the short-circuit wave, and it was observed that the latch-up behavior does not occur even after the lapse of time. On the other hand, with reference to the gate voltage, the collector voltage, and the collector current of Condition 2, it was observed that the collector current overshot, significantly exceeded the steady value indicated in Condition 1, and a behavior which results in the latch-up was observed.

As described above, according to the semiconductor device 101, it was found that the breakdown resistance can be improved by providing the emitter region 25 having the width W1 narrower than the width W3 of the emitter region 25 of the semiconductor device 201.

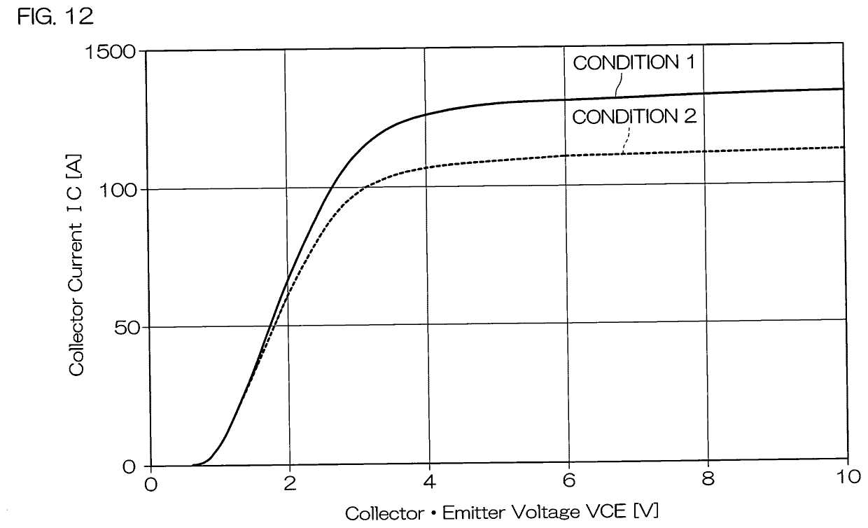

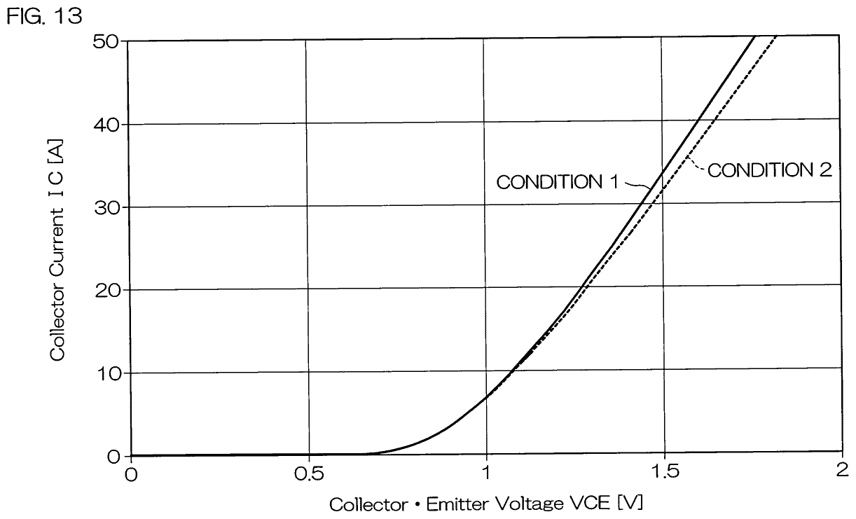

FIG. 12 is a graph in which the current-voltage characteristics of the semiconductor device 101 according to Condition 1 and the semiconductor device 201 according to Condition 2 are obtained by simulation. FIG. 13 is an enlarged view of a part of the graph of FIG. 12. Referring to FIGS. 12 and 13, the ordinate indicates the collector current IC [A], and the abscissa indicates the collector-emitter voltage VCE [V]. FIG. 13 is a graph in which the collector-emitter voltage VCE in FIG. 12 is in a range of 0 V to 2 V.

In FIG. 12, the characteristics of the semiconductor device 101 according to Condition 1 is indicated by the solid line plot, and the characteristics of the semiconductor device 201 according to Condition 2 is indicated by the broken line plot. Both Condition 1 and Condition 2 show current-voltage characteristics when the collector-emitter voltage VCE is changed from 0 V to 10 V.

Referring to the characteristics according to Condition 1, in the semiconductor device 101, the collector-emitter voltage VCE was 1.26 V, 1.60 V, 1.91 V, 2.25 V, and 2.66 V when the collector current IC was 20 A, 40 A, 60 A, 80 A, and 100 A, respectively. On the other hand, referring to the characteristics according to Condition 2, in the semiconductor device 201, the collector-emitter voltage VCE was 1.28 V, 1.65 V, 2.01 V, 2.42 V, and 3.20 V when the collector current IC was 20 A, 40 A, 60 A, 80 A, and 100 A, respectively.

As described above, according to the semiconductor device 101, it was found that the on-loss can be reduced because the collector-emitter voltage VCE necessary for a rising operation can be reduced as compared with the semiconductor device 201.

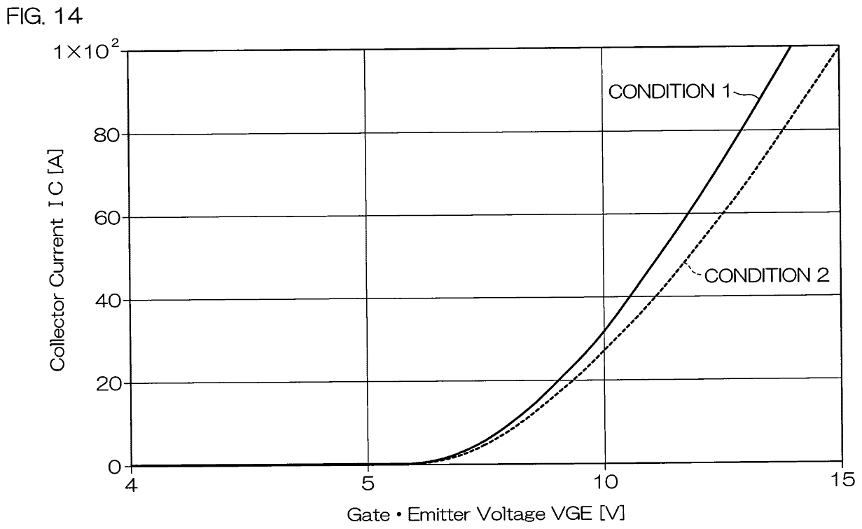

FIG. 14 is a graph in which the current-voltage characteristics of the semiconductor device 101 according to Condition 1 and the semiconductor device 201 according to Condition 2 are obtained by simulation. Referring to FIG. 14, the ordinate indicates the collector current IC [A], and the abscissa indicates a gate-emitter voltage VGE [V]. In FIG. 14, the characteristics of the semiconductor device 101 according to Condition 1 is indicated by the solid line plot, and the characteristics of the semiconductor device 201 according to Condition 2 is indicated by the broken line plot. Both Condition 1 and Condition 2 show current-voltage characteristics when the gate-emitter voltage VGE is changed from 0 V to 15 V.

### <<Description of Structure of Semiconductor Device 81 (Second Preferred Embodiment)>

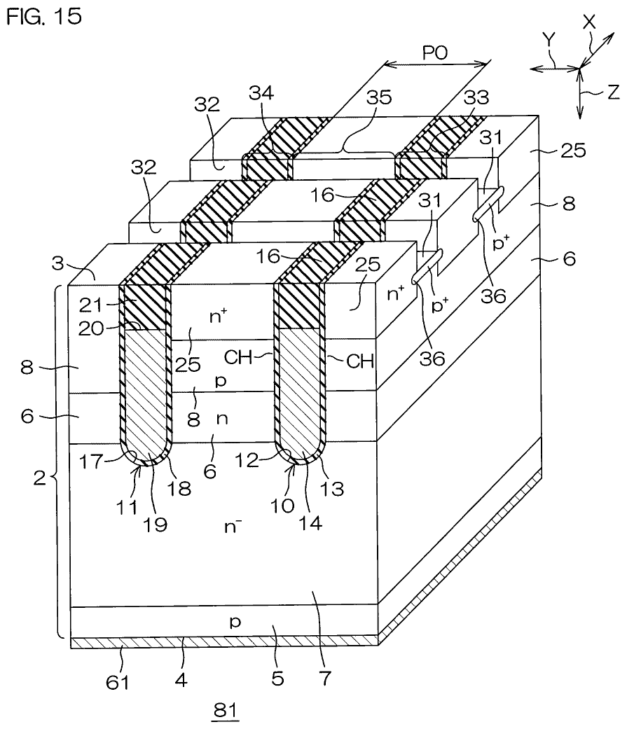

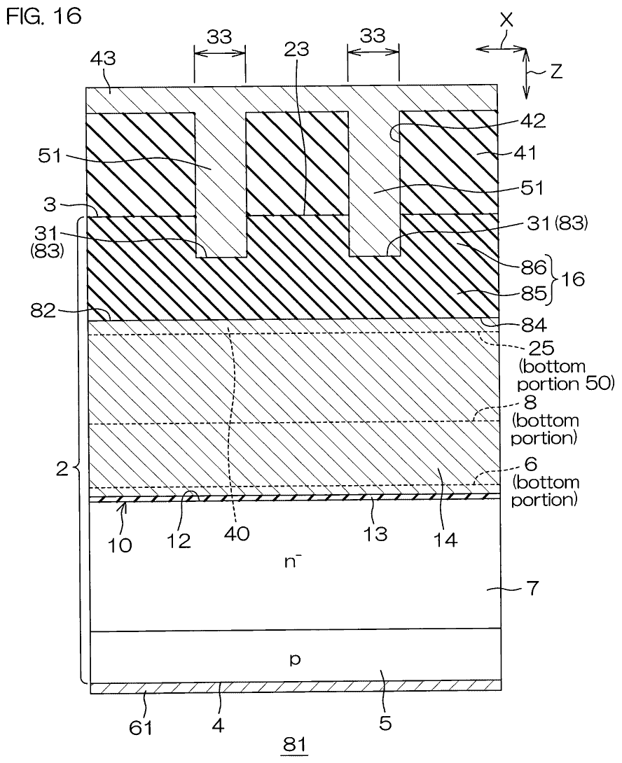

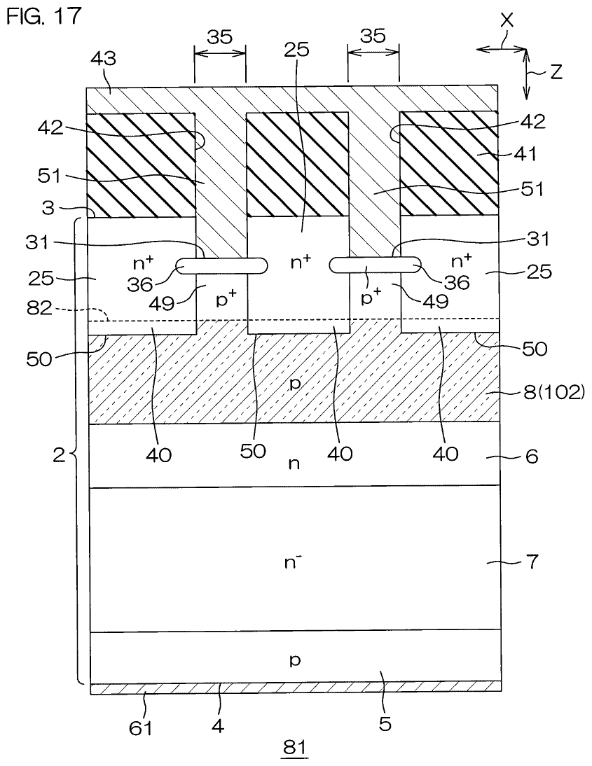

FIG. 15 is a schematic cross-sectional perspective view illustrating a partial region of a semiconductor device 81 according to a second preferred embodiment of the present disclosure. FIG. 16 is a schematic cross-sectional view illustrating a part of the semiconductor device 81 in FIG. 15. FIG. 17 is a schematic cross-sectional view illustrating a part of the semiconductor device 81 in FIG. 15. In the following, structures corresponding to the structures described with the semiconductor device 1 shall be provided with the same reference symbols and description thereof shall be omitted.

With reference to the semiconductor device 1 described above, an example in which the gate electrode layer 14 has the uneven structure including the plurality of gate electrode recess portions 15 has been described. On the other hand, in the semiconductor device 81, a gate electrode layer 14 has a flat structure formed by a depth position of an upper surface 82 being constant over its entirety. More specifically, referring to FIGS. 16 and 17, the upper surface 82 of the gate electrode layer 14 is positioned in the region between a first principal surface 3 and a bottom portion 50 of the emitter region 25 in a normal direction Z. As a result, in the same way as the semiconductor device 1, the emitter region 25 has the facing portion 40 facing the gate electrode layer 14 via the gate insulating layer 13 near the first intersection region 33 in a first direction X.

Referring to FIG. 16, a gate covering insulating layer 16 has an integral structure extending across the plurality of contact trenches 31 along the first direction X. The gate covering insulating layer 16 has an insulating layer uneven structure formed by an insulating layer recess portion 83 formed in the first intersection region 33 of each contact trench 31. The emitter contact electrode layer 51 is embedded in the insulating layer recess portion 83. More specifically, the gate covering insulating layer 16 may include a base portion 85 having a flat lower surface 84 in contact with the upper surface 82 of the gate electrode layer 14 along the first direction X, and a projection portion 86 projecting from the base portion 85 between the adjacent insulating layer recess portions 83. The uneven structure of the gate covering insulating layer 16 is formed by alternately arraying the projection portion 86 and the insulating layer recess portion 83 along the first direction X.

As described above, even with the semiconductor device 81, the same effects as the effects described for the semiconductor device 1 can be exhibited. That is, the entire region of the body region 8 in the first direction X can be set as a channel forming region 102 in which the channel CH can be formed. The semiconductor device 81 can be manufactured by digging down substantially the entirety of the principal surface of a base conductor layer 74 without patterning the base conductor layer 74 during etching of the base conductor layer 74 in the method for manufacturing the semiconductor device 1 (see FIG. 8F).

### <<Description of Structure of Semiconductor Device 91 (Second Preferred Embodiment)>

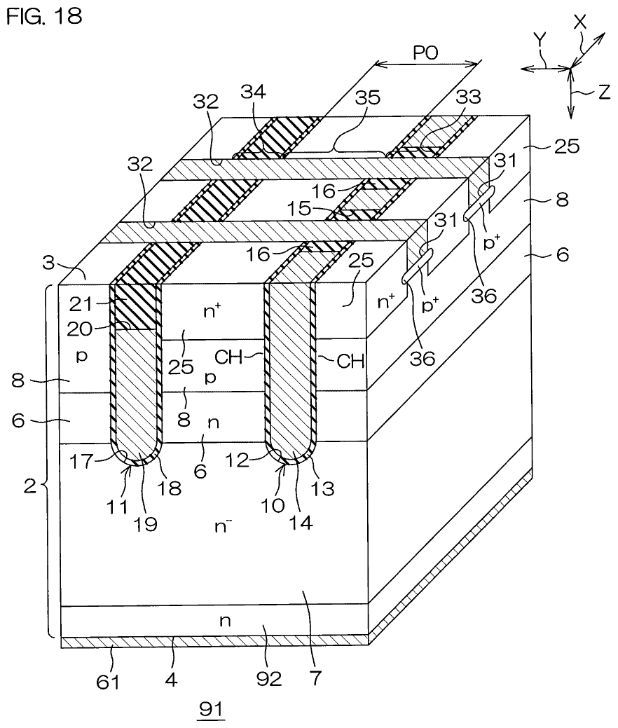

FIG. 18 is a schematic cross-sectional perspective view illustrating a partial region of a semiconductor device 91 according to a third preferred embodiment of the present disclosure. In the following, structures corresponding to the structures described with the semiconductor device 1 shall be provided with the same reference symbols and description thereof shall be omitted.

With the semiconductor device 1 described above, an example in which the p-type collector region 5 is formed in the surface portion of the second principal surface 4 has been described. On the other hand, in the semiconductor device 91, instead of the p-type collector region 5, a drain region 92 of the n-type is formed in the surface portion of a second principal surface 4. Hence, the semiconductor device 91 has a basic form including a trench-gate type MISFET (Metal Insulator Semiconductor Field Effect Transistor). The description of the semiconductor device 1 above applies to a description of the semiconductor device 91 by reading “emitter” as “source” and by reading “collector” as “drain.”

As described above, even with the semiconductor device 91, the same effects as the effects described for the semiconductor device 1 can be exhibited. The semiconductor device 91 can be manufactured only by forming the n-type drain region 92 instead of the p-type collector region 5 and by changing the layout of each mask in the manufacturing method of the semiconductor device 1.

Although preferred embodiments of the present disclosure have been described above, the present disclosure can be implemented in yet other preferred embodiments.

For example, in each of the preferred embodiments described above, a structure in which the conductivity types of the respective semiconductor portions are inverted may be adopted. That is, a p-type portion may be made to be of an n-type and an n-type portion may be made to be of a p-type.

With each of the preferred embodiments described above, an example in which chip 2 is constituted of a silicon monocrystal has been described. However, the chip 2 may include SiC. Also, the chip 2 may be constituted of an SiC monocrystal.

Thus, the preferred embodiments of the present disclosure in all respects are illustrative and not to be interpreted to be restrictive and are intended to include modifications in all respects.

The following appended features can be extracted from the descriptions in this Description and the drawings.

### Appendix 1-1

A semiconductor device (1, 81, 91, 101) including:
a chip (2) having a first principal surface (3) in which a gate trench (12) having a bottom wall and a side wall and extending in a first direction (X) is formed;
a body region (8) of a first conductivity type formed along the side wall of the gate trench (12) in a surface portion of the first principal surface (3);
a first impurity region (25) of a second conductivity type formed along the side wall of the gate trench (12) in a surface portion of the body region (8);
a gate insulating layer (13) formed on the bottom wall and the side wall of the gate trench (12);
a gate electrode (14) embedded in the gate trench (12) and facing the body region (8) and the first impurity region (25) across the gate insulating layer (13);
a contact trench (31) including an intersection region (33) intersecting the gate trench (12) and led from the intersection region (33) to an outside of the gate trench (12) along a second direction (Y) intersecting the first direction (X); and
a contact electrode (51) embedded in the contact trench (31) and electrically connected to the body region (8) and the first impurity region (25) inside the contact trench (31),
wherein a space region (15) is formed in the gate electrode (14) at least in the intersection region (33) and a peripheral portion (9) of the intersection region (33) in the gate trench (12),
a covering insulating layer (16) covering an upper surface (23) of the gate electrode (14) in the intersection region (33) and the peripheral portion (9) of the intersection region (33) and insulating the gate electrode (14) and the contact electrode (51) from each other is embedded in the space region (15), and
the first impurity region (25) is formed deeper than the upper surface (23) of the gate electrode (14) in the peripheral portion (9) of the intersection region (33).

### Appendix 1-2

The semiconductor device (1, 81, 91, 101) according to Appendix 1-1, wherein the first impurity region (25) includes a facing portion (40) facing the gate electrode (14) below the peripheral portion (9) of the intersection region (33).

### Appendix 1-3

The semiconductor device (1, 81, 91, 101) according to Appendix 1-1 or Appendix 1-2, wherein the contact electrode (51) is connected to the body region (8) at a bottom wall of the contact trench (31) and is connected to the first impurity region (25) at a side wall of the contact trench (31).

### Appendix 1-4

The semiconductor device (1, 81, 91, 101) according to any one of Appendix 1-1 to Appendix 1-3, wherein a width (W1) of the first impurity region (25) in the first direction (X) is 1.0 μm or less.

### Appendix 1-5

The semiconductor device (1, 81, 91, 101) according to Appendix 1-4, wherein the width (W1) of the first impurity region (25) is 0.5 μm or more and 1.0 μm or less.

### Appendix 1-6

The semiconductor device (1, 81, 91, 101) according to any one of Appendix 1-1 to Appendix 1-5, wherein the peripheral portion (9) of the intersection region (33) includes a region in a range of 0.05 μm or more and 0.5 μm or less from the intersection region (33).

### Appendix 1-7

The semiconductor device (1, 91, 101) according to any one of Appendix 1-1 to Appendix 1-6, further including a plurality of the contact trenches (31) formed at intervals along the first direction (X),
wherein the gate electrode (14) has an electrode uneven structure formed by a gate electrode recess portion (15) formed in the intersection region (33) of each of the contact trenches (31) and the peripheral portion (9) of the intersection region (33) along the first direction (X), and
the covering insulating layer (16) is embedded in the gate electrode recess portion (15).

### Appendix 1-8

The semiconductor device (1, 91, 101) according to Appendix 1-7, wherein the covering insulating layer (16) is embedded independently for each of the gate electrode recess portions (15), and
a part of the upper surface (23) of the gate electrode (14) is exposed between the adjacent contact trenches (31).

### Appendix 1-9

The semiconductor device (1, 91, 101) according to Appendix 1-7 or Appendix 1-8, wherein the gate electrode recess portion (15) is formed across the peripheral portion (9) on one side and the peripheral portion (9) on the other side of the intersection region (33) in the first direction (X), and
the covering insulating layer (16) includes a first portion (47) disposed in the intersection region (33) and a second portion (48) disposed in each of the peripheral portion (9) on one side and the peripheral portion (9) on the other side in the first direction (X) with respect to the first portion (47).

### Appendix 1-10

The semiconductor device (1, 91, 101) according to any one of Appendix 1-7 to Appendix 1-9, wherein a width (W6) of the contact trench (31) in the first direction (X) is 0.3 μm or more and 1.0 μm or less, and
side walls of the gate electrode recess portion (15) are formed at an interval of 0.05 μm or more and 0.5 μm or less on both sides of the contact trench (31) in the first direction (X).

### Appendix 1-11

The semiconductor device (81) according to any one of Appendix 1-1 to Appendix 1-6, further including a plurality of the contact trenches (31) formed at intervals along the first direction (X).
wherein the gate electrode (14) has a flat structure formed by the depth position of the upper surface (82) being constant throughout the upper surface.

### Appendix 1-12

The semiconductor device (81) according to Appendix 1-11, wherein the covering insulating layer (16) has an integral structure extending across a plurality of the contact trenches (31) along the first direction (X) and has an insulating layer uneven structure formed by an insulating layer recess portion (83) formed in the intersection region (33) of each of the contact trenches (31), and
the contact electrode (51) is embedded in the insulating layer recess portion (83).

### Appendix 1-13

The semiconductor device (81) according to Appendix 1-12, wherein the covering insulating layer (16) includes a base portion (85) having a flat lower surface (84) in contact with the upper surface (82) of the gate electrode (14) along the first direction (X) and a projection portion (86) projecting from the base portion (85) between the adjacent insulating layer recess portions (83), and
the insulating layer uneven structure is formed by alternately arraying the projection portion (86) and the insulating layer recess portion (83) along the first direction (X).

### Appendix 1-14

The semiconductor device (1, 81, 101) according to any one of Appendix 1-1 to Appendix 1-13, wherein the first impurity region (25) includes an emitter region (25), and
the contact electrode (51) includes an emitter contact electrode (51).

### Appendix 1-15

The semiconductor device (91) according to any one of Appendix 1-1 to Appendix 1-13, wherein the first impurity region (25) includes a source region (25), and
the contact electrode (51) includes a source contact electrode (51).

1. A semiconductor device comprising:
a chip having a first principal surface in which a gate trench having a bottom wall and a side wall and extending in a first direction is formed;
a body region of a first conductivity type formed along the side wall of the gate trench in a surface portion of the first principal surface;
a first impurity region of a second conductivity type formed along the side wall of the gate trench in a surface portion of the body region;
a gate insulating layer formed on the bottom wall and the side wall of the gate trench;
a gate electrode embedded in the gate trench and facing the body region and the first impurity region across the gate insulating layer;
a contact trench including an intersection region intersecting the gate trench and led from the intersection region to an outside of the gate trench along a second direction intersecting the first direction; and
a contact electrode embedded in the contact trench and electrically connected to the body region and the first impurity region inside the contact trench,
wherein a space region is formed in the gate electrode at least in the intersection region and a peripheral portion of the intersection region in the gate trench,
a covering insulating layer covering an upper surface of the gate electrode in the intersection region and the peripheral portion of the intersection region and insulating the gate electrode and the contact electrode from each other is embedded in the space region, and
the first impurity region is formed deeper than the upper surface of the gate electrode in the peripheral portion of the intersection region.

2. The semiconductor device according to claim 1, wherein the first impurity region includes a facing portion facing the gate electrode below the peripheral portion of the intersection region.

3. The semiconductor device according to claim 1, wherein the contact electrode is connected to the body region at a bottom wall of the contact trench and is connected to the first impurity region at a side wall of the contact trench.

4. The semiconductor device according to claim 1, wherein a width of the first impurity region in the first direction is 1.0 μm or less.

5. The semiconductor device according to claim 4, wherein the width of the first impurity region is 0.5 μm or more and 1.0 μm or less.

6. The semiconductor device according to claim 1, wherein the peripheral portion of the intersection region includes a region in a range of 0.05 μm or more and 0.5 μm or less from the intersection region.

7. The semiconductor device according to claim 1, further comprising a plurality of the contact trenches formed at intervals along the first direction,
wherein the gate electrode has an electrode uneven structure formed by a gate electrode recess portion formed in the intersection region of each of the contact trenches and the peripheral portion of the intersection region along the first direction, and
the covering insulating layer is embedded in the gate electrode recess portion.

8. The semiconductor device according to claim 7, wherein the covering insulating layer is embedded independently for each of the gate electrode recess portions, and
a part of the upper surface of the gate electrode is exposed between the adjacent contact trenches.

9. The semiconductor device according to claim 7, wherein the gate electrode recess portion is formed across the peripheral portion on one side and the peripheral portion on the other side of the intersection region in the first direction, and
the covering insulating layer includes a first portion disposed in the intersection region and a second portion disposed in each of the peripheral portion on one side and the peripheral portion on the other side in the first direction with respect to the first portion.

10. The semiconductor device according to claim 7, wherein a width of the contact trench in the first direction is 0.3 μm or more and 1.0 μm or less, and
side walls of the gate electrode recess portion are formed at an interval of 0.05 μm or more and 0.5 μm or less on both sides of the contact trench in the first direction.

11. The semiconductor device according to claim 1, further comprising a plurality of the contact trenches formed at intervals along the first direction,
wherein the gate electrode has a flat structure formed by the depth position of the upper surface being constant throughout the upper surface.

12. The semiconductor device according to claim 11, wherein the covering insulating layer has an integral structure extending across a plurality of the contact trenches along the first direction and has an insulating layer uneven structure formed by an insulating layer recess portion formed in the intersection region of each of the contact trenches, and
the contact electrode is embedded in the insulating layer recess portion.

13. The semiconductor device according to claim 12, wherein the covering insulating layer includes a base portion having a flat lower surface in contact with the upper surface of the gate electrode along the first direction and a projection portion projecting from the base portion between the adjacent insulating layer recess portions, and
the insulating layer uneven structure is formed by alternately arraying the projection portion and the insulating layer recess portion along the first direction.

14. The semiconductor device according to claim 1, wherein the first impurity region includes an emitter region, and
the contact electrode includes an emitter contact electrode.

15. The semiconductor device according to claim 1, wherein the first impurity region includes a source region, and
the contact electrode includes a source contact electrode.
